(19) United States
(12) Patent Application Publication
(10) Pub. No.: US 2013/0309613 A1
(43) Pub. Date: Nov. 21, 2013

(54) Liquid Based Films

(71) Applicant: CORNING INCORPORATED, CORNING, NY (US)

(72) Inventors: Shawn Michael O'Malley, Horseheads, NY (US); Vitor Marino Schneider, Painted Post, NY (US)

(73) Assignee: CORNING INCORPORATED, CORNING, NY (US)

(21) Appl. No.: 13/892,536

(22) Filed: May 13, 2013

Related U.S. Application Data
(60) Provisional application No. 61/647,815, filed on May 16, 2012.

(51) Int. Cl. H01L 31/18

(52) U.S. Cl. CPC H01L 31/1884
USPC 430/319; 427/74

(57) ABSTRACT

Inorganic films made by providing a solution comprising a metallic salt, an organo-metallic compound, or combinations thereof in a polar aprotic solvent, depositing the solution onto a substrate to form a coating on the substrate, and annealing the coating.

### CROSS-REFERENCE TO RELATED APPLICATIONS

This application claims the benefit of priority under 35 U.S.C. §119 of U.S. Provisional Application Ser. No. 61/647,815, filed on May 16, 2012, the content of which is relied upon and incorporated herein by reference in its entirety.

### BACKGROUND

1. Field

The disclosure relates to liquid based films, and more particularly to transparent conductive oxides (TCO) films, for example, conductive AZO TCO films and methods of making the same.

2. Technical Background

A common keystone component for both display and photovoltaic (PV) technologies is the use of low-cost, high quality TCOs. Typically, commercial grade TCOs are deposited on glass substrates either using sputtering, chemical vapor deposition (CVD), or spray pyrolysis among other techniques. All of these previously mentioned manufacturing techniques usually require either a high temperature deposition process, or the use of vacuum systems that may be quite expensive and not compatible with a continuous processing, for example, roll-to-roll manufacturing. In addition, these deposition techniques do not enable printed electronics.

Indium tin oxide (ITO) is currently the industry standard material for TCO films with low resistivity and a high degree of transparency. However, ITO is also well known to be toxic and relatively expensive when compared to the glass substrates due to the high cost of indium. An alternative TCO is aluminum zinc oxide (AZO). AZO, while being non-toxic and lower in cost relative to ITO, does possess a weaker conductivity than the more common ITO material.

Farley (2004) discloses making ZnO films (without any Al doping but with Co, Fe and Mn doping) in order to have a highly ordered film. The applications are not related to transparent conducting films and conductivity is not reported. Huang (2010) discloses ZnO films and methods of making ZnO films and reports the different changes in shape of ZnO nanocrystals using depending on the sol-gel chemistry used.

It would be advantageous to have a method of making an AZO film which is conductive, reduces manufacturing costs and/or can optimize film quality.

### SUMMARY

Sol-gel based TCOs can be deposited at room temperature via, for example, dip-coating or spin-coating among other techniques under a normal environment, at very low cost, and may be compatible with a large on-draw or roll-to-roll manufacturing process. A method not requiring high temperature deposition or a vacuum environment is advantageous. The second step after deposition is sintering at moderate temperatures, from 300° C. to 600° C., that can be also done in a non-vacuum environment and perhaps can be also implemented on-line or roll-to-roll. The third step is the crystallization step that in this case requires a controlled atmosphere (N2 or Ar) for eg. 5 hours at 300° C. to 600° C. and can be done after the cutting of the glass and in a batch process that can be economical.

All these are potential advantages of a liquid based TCO, however, one of the main difficulties in the implementation of such process is the fact that the solution can be rather unstable due to the hydrolysis leading to precipitation and uneven results over time.

The disclosed methods can be used to make a very stable solution that can produce TCOs of medium electric quality (resistivity of 6.4 10⁻² Ohm·cm).

In one embodiment, polar aprotic solvents as a means to prepare stable formulations which enable the formation of conducting transparent AZO films. The polar aprotic solvents have unique ion solvating properties that greatly facilitate the process of making an AZO precursor solution.

In addition a second application is that these solvent systems allow for the introduction of conductive agents like carbon nanotubes, C60, C70, graphene and graphane to be incorporated directly into the TCO film. The data shows that the introduction of one of these agents namely graphene can improve conductivity while maintaining transparency. While not constrained by theory, these conductive bridge agents provide a means for allowing more cross transport of electrons. So, again the present invention is specifically (1) a process and a stable chemical solvent system which enables AZO films to be formed inexpensively and (2) that these formulations allow for the introduction of conductive agents which improve conductivity. The films described herein can be used as “seed layers” for subsequent growth of AZO films over this initial AZO film.

Polar aprotic solvents such as dimethylformamide (DMF) and/or n-methylpyrrolidone (NMP) can be used to produce stable solution based zinc oxide (ZO), aluminum zinc oxide (AZO), and also metal-semiconductor hybrid doped aluminum zinc oxide (hybrid -AZO) solutions. These ion based aprotic polar solvent solutions enable the process of making TCO films.

The films exhibit good optical properties and good conductivity (that still has room for improvement). The use of additional semiconductor and nanometal doping into the liquid form AZO helps to increase the conductivity and may have other effects such as plasmonics.

The films are used for two different applications: 1) conductive transparent film and/or 2) controlled rough nanometric surface.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 is a schematic illustration of the method, according to one embodiment, to produce AZO films from a stable precursor based on a multilayer deposition process with annealing of layer and followed by a crystallization step of the sample. The Molarities of the precursor may vary in our particular case, X is 0.6 M and Y is 0.1 M, most of the time. A catalyst based on a 0.1 M HCL in water may be added for hydrolysis at R=2 with desired Al to Zn ratio. * here the solution can be doped with the conducting agent like grapheme or silver nanorods to facilitate increased conductivity.

FIG. 2 is a graph of optical absorption measurements of AZO films deposited in 1737 glass with different concentration of Al atom % doping. It is known that the optimum conductivity is achieved at around 0.8 at % of Al in ZnO [2]. However, this does not necessarily generate the best optical transparent film. Here the total film thickness is around 50 nm and a reference glass slide is present to account for reflection losses at the interface. Overall the film is of good optical quality in the visible with major cutoff only around 390 nm in the UV range.

FIG. 3 is a photograph of articles, according to some embodiments, with 0.8 at %, 1.0 at %, 2 at % and 4 at % in contrast with a bare uncoated glass slide.

FIGS. 4A and 4B are SEM micrographs of articles according to some embodiments, for example, a 0.8 at % AZO film processed with 4 layers of spin coater at 4000 rpm for 30 sec, hotplate temperature of 400° C. for 1 minute for annealing between layers, and crystallization at 500° C. for 5 hours (In FIG. 4B only, where large bumps are dirt due to non-clean room environment of the process). FIG. 4A is an article after coating of 4 layers and no crystallization. FIG. 4B is an article after coating of 4 layers and crystallization at 500° C. for 5 hours. (here, larger bumps are dirt due to non-clean room environment of the process).

FIG. 5 is a graph of measured conductivity from combined 4 point resistance (sheet resistance) and ellipsometry (thickness). Here, the experiment shows how for a same condition the resistivity is varying with the crystallization temperature. One shows that for a 0.8 atomic mole percent (at %) Al in ZnO film made of 4 layers deposited at a hot-plate temperature of 350° C. after spin coating at 4000 RPM for 1 minute that two minimal points occur. One at high temperature and one at the low end of the temperature range. Here VWR soda-lime glass slides were used.

FIG. 6 is a graph of measured conductivity from combined 4 point resistance (sheet resistance) and ellipsometry (thickness). Here, the experiment shows how for a same condition the resistivity is varying with the hot-plate annealing temperature. One shows that for a 0.8 at % Al in ZnO film made of 4 layers deposited at different hot plate temperatures after spin coating at 4000 RPM for 1 minute. Here, all samples were crystallized at 500° C. for 5 hours. The graph shows that the higher annealing temperature reduces the overall resistivity of the film. At the moment we are limited by the temperature of the hot-plate around 450° C.

FIG. 7 is a graph of XRD measured of two AZO films made of 0.8 at % Al on ZnO processed with 4 layers at 4000 RPM for 30 sec and annealed at 400° C. for 1 min between layers. Here these 2 films are crystallized under different conditions. The film crystallized under Nitrogen/air is basically not very conductive while the film crystallized under Argon is of normal (average) conductivity. There is virtually no difference based on the XRD spectra and grain size to account for the difference in conductivity leading to the hypothesis that additional factors may be at play.

FIG. 8 is a graph of measured conductivity from combined 4 point resistance (sheet resistance) and ellipsometry (thickness). Here, the samples were a 0.8 at % Al in ZnO film made of 4 layers deposited at a temperature of 425° C. after spin coating at 4000 RPM for 1 minute. After each spin coating the sample. The sample waited prior to hot plate sintering 20 minutes, 5 minutes, 5 minutes and 20 minutes for settling and further hydrolysis. Here, all samples were crystallized at 300° C. for different periods of time of 1 hour, 5 hours and 24 hours. The graph shows that the higher annealing duration reduces the overall resistivity of the film. At the moment we are limited by the temperature of the hot-plate around 450° C. Also the additional wait time prior to hot-plate sintering is providing additional benefits leading to our current lowest resistivity achieved of 2.32e-2 Ohm·cm.

FIG. 9 is a photograph of samples of bare glass slide and a Graphene doped AZO sample (2× Graphene).

FIG. 10 is a graph of enhancement obtained by co-doping the AZO film with a semiconductor/metallic nanostructured particle. In this case graphene was used to enhance the conductivity of the AZO films. Here solutions of 1× amount of graphene and 2× amount of graphene were used and compared.

### DETAILED DESCRIPTION

Reference will now be made in detail to the present preferred embodiment(s), an examples of which is/are illustrated in the accompanying drawings. Whenever possible, the same reference numerals will be used throughout the drawings to refer to the same or like parts.

The present invention may provide one more of the advantages described below.

The use of aprotic solvents to make a stable ionic TCO film forming precursor solutions, such as, aluminum zinc oxide (AZO) solutions may be valuable to the industry. In addition, the disclosed AZO solutions have not shown any sign of precipitation for several weeks under normal ambient air environment storage. This discovery allows manufacturers ease of use.

These AZO solutions in aprotic solvents produce highly transparent zinc oxide and aluminum zinc oxide films. Furthermore, the aprotic solvents should provide the same or better degree of stability as any other prospective ionic TCO formers such as tin oxides (SnO₂).

The transparent films formed from the AZO aprotic solvent precursor solutions present good conductivity (resistivity of 2.32 10⁻² Ohm·cm at moment for our best results) and it is believed that with some further optimization they can achieve sputtering grade AZO film conductivity (2.0 10⁻³ Ohm·cm).

The deposition process is made at “room temperature in normal air conditions” (No vacuum systems are required). This opens the door to the manufacture of printable TCOs which is unique and is clearly distinguishable from prior CVD and PCVD approaches. Conceivably, ink jet printing, spray, ultrasonic mist or even PDMS like stamping of the aprotic solvent TCO precursor solutions can be done on any surface and under ambient conditions.

Due to its liquid form precursors other agents can be added which yield new admixture properties. The degree of solvent proportion control is very tunable and allows easy control of the stoichiometric proportion of admixed agents.

The aprotic solvents are useful for suspension and dissolution of semiconducting and conducting metals such as graphene, carbon nanotubes, silver/gold/platinum nanowires/nanodots and other metallic nanoparticles. The data demonstrates that the addition of conductive and semi-conductive agents like graphene into the AZO formulation can improve conductivity. The aprotic solvent system allows the ability to control of the proportion of graphene doped into the AZO film and that this addition may cause an enhanced conductivity of the film.

The process has a sintering thermal process and a separate crystallization step that can be controlled for a variety of different results in particular when one is interested in the roughness of the substrate for additional light scattering, for example, for photovoltaic applications.

The use of unusual semiconductor/metal nano-particles can lead to optical and electrical different properties as well as increased conductivity.

The films can be used as seed layers for subsequent AZO synthesis by CVD, sputtering, spray pyrolysis, and others type processes.

The films can be prepared on a number of surfaces and substrate geometries and surface textures such as flat glass, glass fiber or Vycor®. Regarding this last point, liquid deposition of the precursor solution using the aprotic solvent system can enable TCOs to be located onto roughened surfaces. This capability may allow coating TCOs conformally over light scattering surfaces without disrupting the desired optical properties.

Here for sake of illustration and proof of principle VWR soda lime glass slides and Corning 1737 glass slides were used, however, other glass compositions, for example, being developed for PV or even HPFS could be used for the same purpose.

The advancement of display systems and the current need for efficient thin-film solar cells sparked a renewed interest on TCOs. Among the TCO's of interest one may mention ITO and AZO. The later has the advantage of being non-toxic and with precursors abundant in nature, in contrast to indium used in ITO.

In one embodiment, conductive AZO films and AZO films doped with graphene have improve conductivity. The use of polar aprotic solvents is advantageous because the aprotic polar solvents have unique solvating properties. Polar aprotic solvents may be described as solvents that share ion dissolving power with protic solvents but lack an acidic hydrogen. These solvents generally have intermediate dielectric constants and polarity. Common characteristics of aprotic solvents are: solvents do not display hydrogen bonding, solvents do not have an acidic hydrogen, and solvents are able to stabilize ions.

As such, it has been found that these solvents do enable the formation of stable ion containing solutions that when deposited and heat treated can yield effective TCO films.

In one embodiment, polar aprotic solvents like DMF can be used to make doped ZnO with Aluminum to produce good optical quality conductive films via a stable solution.

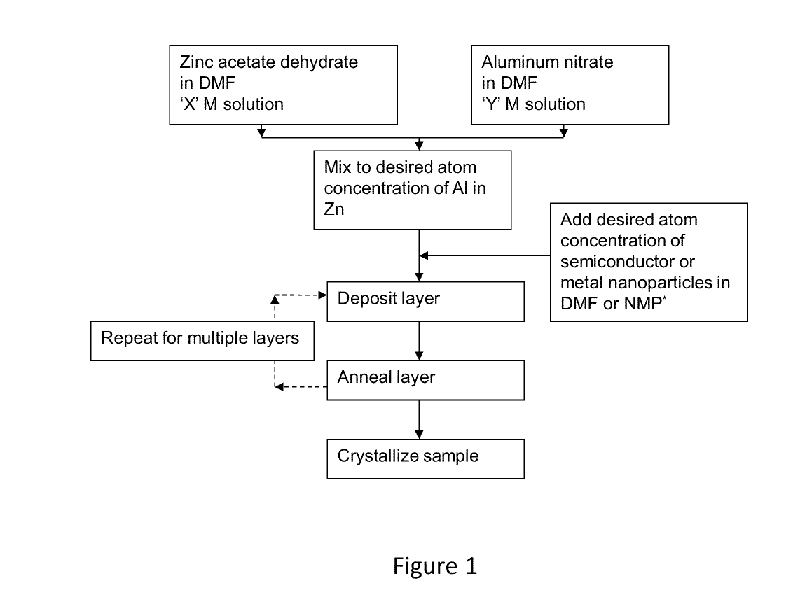

The typical process flow to produce these stable liquid based TCO's in this case AZO but also could be ITO, gallium doped zinc oxide (GZO), boron doped zinc oxide (BZO), and fluorine doped zinc oxide (FZO TCO formulations). FIG. 1 shows our scheme for the general formulation deposition approach.

Here initially Zinc acetate dehydrate (Zn(CH₃COO)₂. 2H₂O, 99.999% pure from Sigma-Aldrich) is used and dissolved in N,N-dimethylformamide (DMF) at a molar concentration ‘X’. For sake of completeness we use here 0.6 M. Then Aluminum nitrate nanohydrate (Al(NG₃)₃.9H₂O, 99.997% pure from Sigma-Aldrich) is also dissolved in N,N-dimethylformamide (DMF) at a molar concentration ‘Y’. For sake of completeness we use here 0.1 M. The table 1 below shows the physical properties for some of the aprotic solvents, including DMF.

Table 1 shows a description and selected properties of exemplary Polar Aprotic Solvents.

TABLE 1
Polar Aprotic Solvents

| | | | | | |
|---|---|---|---|---|---|
| Dichloromethane (DCM) | CH₂Cl₂ | 40° C. | 9.1 | 1.3266 g/ml | 1.60 D |
| Tetrahydrofuran (THF) | /—CH₂—CH₂—O—CH₂—CH₂—\ | 66° C. | 7.5 | 0.886 g/ml | 1.75 D |
| Ethyl acetate | CH₃—C(═O)—O—CH₂—CH₃ | 77° C. | 6.0 | 0.894 g/ml | 1.78 D |
| Acetone | CH₃—C(═O)—CH₃ | 56° C. | 21 | 0.786 g/ml | 2.88 D |
| Dimethylformamide (DMF) | H—C(═O)N(CH₃)₂ | 153° C. | 38 | 0.944 g/ml | 3.82 D |
| Acetonitrile (MeCN) | CH₃—C≡N | 82° C. | 37 | 0.786 g/ml | 3.92 D |
| Dimethyl | CH₃—S(═O)—CH₃ | 189° C. | 47 | 1.092 g/ml | 3.96 |
| sulfoxide (DMSO) | | | | | |

The solution ‘X’ and ‘Y’ are then mixed to the desired atomic concentration of Al in Zn forming a doped solution. Alternatively also one can add additional atom concentrations of metallic nanoparticles (such as gold, platinum, silver, aluminum, cooper, etc) or semiconductor nanoparticles (such as carbon nanotubes/nanodots, graphene, graphene oxide, CdS, CdTe) for enhanced properties that may be conductivity or other physical property. Conceivably, even conductive nanometals like silver nanorods could also be doped into our TCO precursor solution to aid in the formation of a transparent conducting oxide film.

The substrate can be used as it is or it can be prepared to enhance its hydrophilic behavior. For example it was noticed that the 1737 and soda-lime glass ‘wet better’ for the initial deposition layer if its hydrophilic behavior is enhanced by an oxygen plasma cleaning prior to the deposition. Notice that this was found true only for the first deposition layer, after the first layer it seems that the surface become more accepting of the DMF solvent. This step may be optional if one wants to improve the contact of solvent with a substrate. Alternatively, piranha type acid cleaning solutions also enhance the wetting properties of substrates.

The solution, for example a 0.8 atom % of Al doped ZnO solution, is then deposited on a substrate (here glass, semiconductor, metal or other) by spin coating, dip-coating, tape-casting or simply washing the substrate on the solution. Spin-coated was used with velocities ranging from 1000 RPM to 4000 RPM for times from 30 seconds to 60 seconds. In one embodiment, a velocity of 4000 RPM for 30 seconds was used in several samples successfully, all this in a normal environment.

The deposited layer on the substrate is then annealed for a certain temperature and for a period of time. Here, the source of heat can be a simple hot-plate, a tube furnace, a normal oven, an open oven with movement, a flash lamp furnace such as a rapid thermal annealer (RTA), a localized heat source such as a flame or laser. In this example, a hot plate was used where the temperature was measured with an external thermocouple for temperature calibration. The hot-plate was used in a normal environment.

The duration of annealing here may be important as well as the rest time after the deposition and after annealing. In our case, we tried rest time after deposition from 1 minute to 1 hour. Duration of the annealing from 1 minute to 1 hour and rest time after the annealing between layers from 1 minute from 1 hour.

If multiple layers are desired, one should repeat the process of deposition and annealing with their respective times multiple times as indicated in the loop in FIG. 1. In our case we did from a single layer to up to 10 layers in our devices, but many more are possible depending on the target desired. Note multi-layer deposition can be an in-line process.

After deposition of single and multiple layers the sample is then crystallized (although in some cases one may not want to do that for a particular reason). The crystallization is made in a controlled environment where the atmosphere is controlled. Here several options are available. We obtained our current results by using an Argon atmosphere inside a glove box, where studies made in crystallization in normal air did not lead to good results in terms of conductivity.

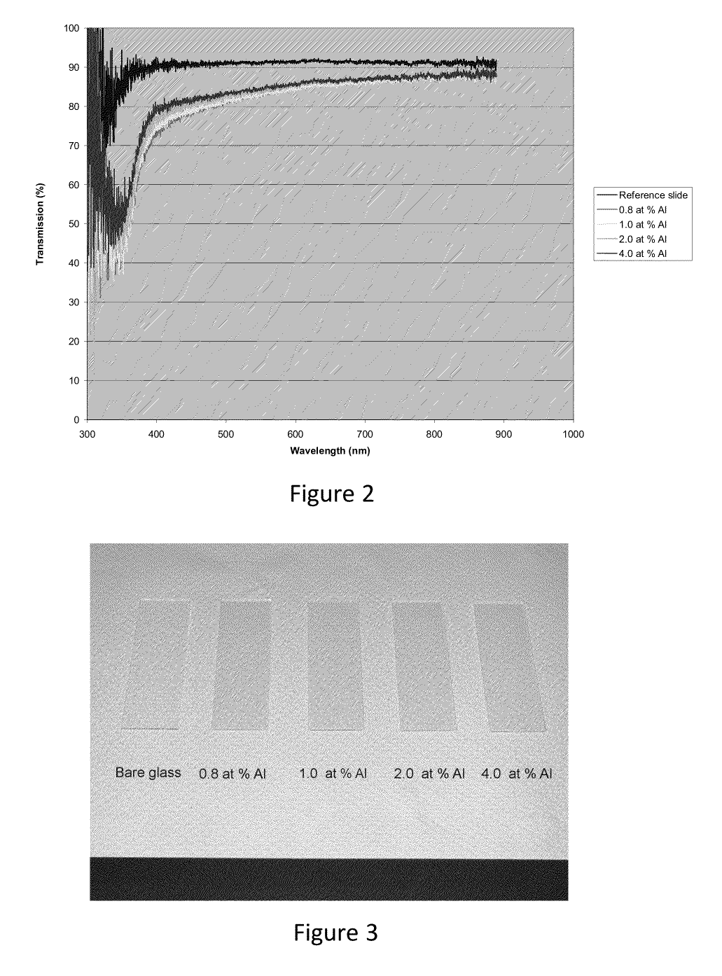

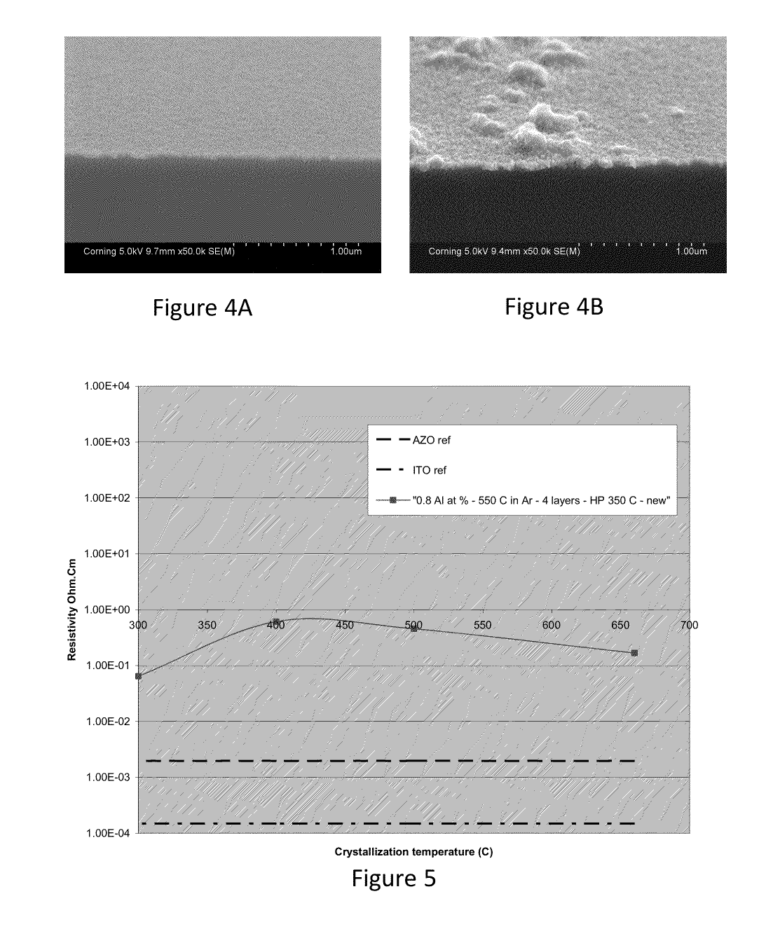

Some examples of the optical transmission of different films manufactured with the process can be observed in FIG. 2. Here, optical absorption measurements of AZO films deposited in 1737 glass with different concentration of Al atom % doping from 0.8 at % to 4.0 at % is presented. It is known that the optimum conductivity is achieved at around 0.8 at % of Al in ZnO. However, this does not necessarily generate the best optical transparent film. Here the total film thickness is around 50 nm and a reference glass slide is present to account for reflection losses at the interface. Overall the film is of good optical quality in the visible with major cutoff only around 390 nm in the UV.

These same samples that were optically measured can be observed in FIG. 3. Here, the photograph shows their contrast when compared to a bare 1737 glass slide.

Additional observation of the sample made with 0.8 at % Al in ZnO can be seen in FIG. 3. Here, SEM micrographs of a 0.8 at % AZO film processed with 4 layers of spin coater at 4000 rpm for 30 sec, hotplate temperature of 400° C. for 1 minute for annealing between layers, and crystallization at 500° C. for 5 hours (sample b only, where large bumps are dirt due to non-clean room environment of the process) are shown in two different conditions. First, one has a sample after coating (4 layers) and no crystallization (item ‘a’). Second, one has a sample after coating of 4 layers and crystallization at 500° C. for 5 hours (item ‘b’). Here, the larger bumps are probably dirt due to non-clean room environment of the process. It is important to notice the nanostructured TCO rough surface. Here its roughness can be controlled by an annealing step, and it is of great interest for the field of photovoltaic cells. It can be added as a seed layer for a thicker TCO growth that may enhance scattering. The surface can be used without crystallization and do not need to be conductive.

In FIG. 5, we study the measured conductivity from combined 4 point resistance (sheet resistance) and ellipsometry (thickness) with the crystallization temperature. Here, the experiment shows how for a same condition (not optimal yet with a lot of room for future improvement) how the resistivity is varying with the crystallization temperature. One shows that for a 0.8 at % Al in ZnO film made of 4 layers deposited at a hot-plate temperature of 350° C. after spin coating at 4000 RPM for 1 minute that two minimal points occur. One at high temperature and one at the low end of the temperature range. Here VWR soda-lime glass slides were used. While the temperature at the higher end makes sense, since higher temperatures will increase the rate of crystallization the minimum at the low temperature range is not clear. A possible explanation is that the resistivity of the film is being impaired by out-diffusion of glass mobile species (such as sodium (Na)). In this case, the low temperature could reduce the mobility of these species but despite of the lower crystallization could lead to a better result for conductivity.

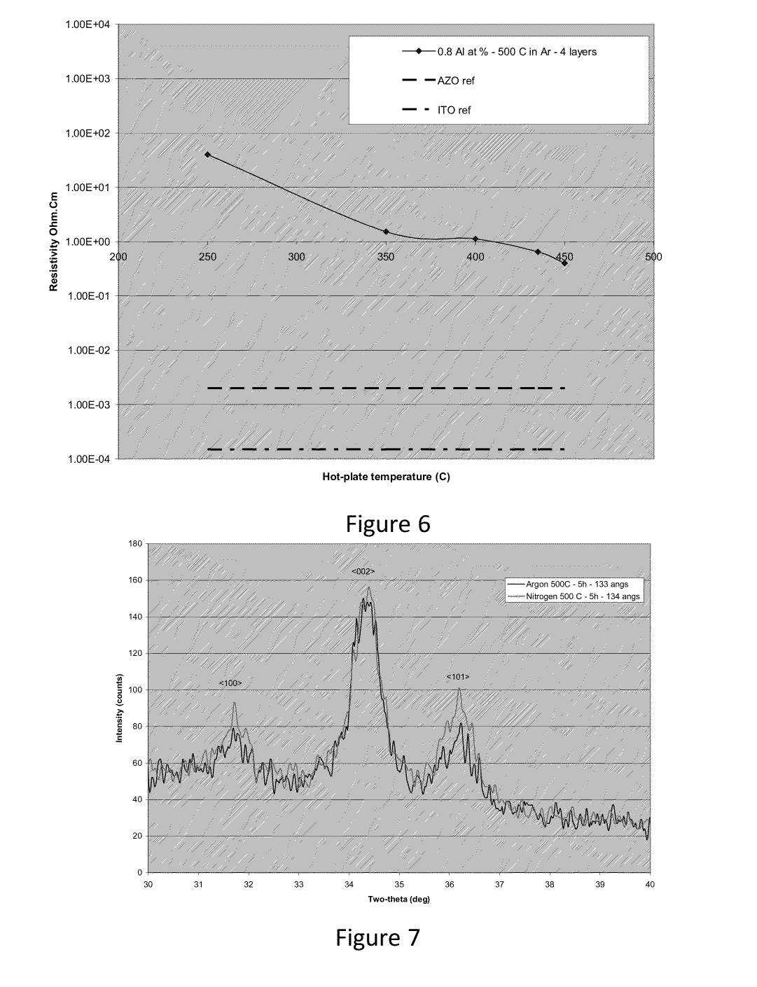

In FIG. 6 shows the measured conductivity from combined 4 point resistance (sheet resistance) and ellipsometry (thickness) with the hot-plate temperature. Here, the experiment shows how for a same condition (not optimal yet with a lot of room for future improvement) the resistivity is varying with the hot-plate annealing temperature. One shows that for a 0.8 at % Al in ZnO film made of 4 layers deposited at different hot plate temperatures after spin coating at 4000 RPM for 1 minute. Here, all samples were crystallized at 500° C. for 5 hours. The graph shows that the higher annealing temperature reduces the overall resistivity of the film. At the moment we are limited by the temperature of the hot-plate around 450° C. However, if one uses tube furnaces, rapid thermal annealer (RTA) or other types of annealing furnaces one can easily go to around 600° C. for sample annealing temperatures that seem to indicate a increase in performance of the TCO. Conceivably, microwave, infrared, radio frequency, laser heating, and/or inductive heating can be used for heating.

In FIG. 7, the graph shows the XRD pattern generated by two AZO films made of 0.8 at % Al on ZnO processed with 4 layers at 4000 RPM for 30 sec and annealed at 400° C. for 1 min between layers. Here these 2 films are crystallized under different conditions. The film crystallized under Nitrogen/air is basically not very conductive while the film crystallized under Argon is of normal (average) conductivity. There is virtually no difference based on the XRD spectra and grain size to account for the difference in conductivity leading to the hypothesis that additional factors may be at play, such as the formation of oxygen bonds that may reduce the conductivity during crystallization.

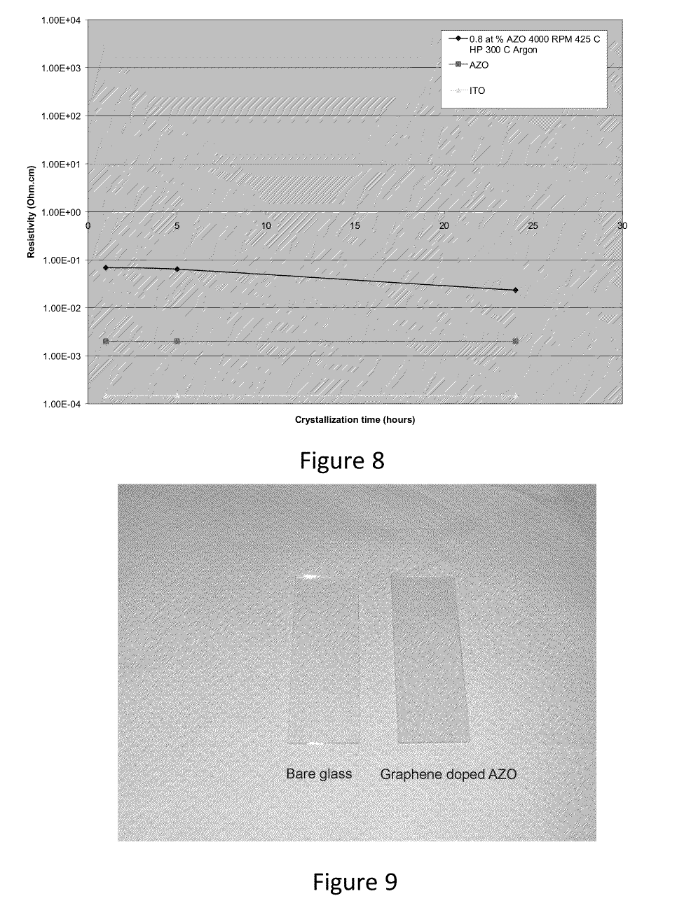

In FIG. 8, the graph shows the measured conductivity from combined 4 point resistance (sheet resistance) and ellipsometry (thickness). Here, the samples were a 0.8 at % Al in ZnO film made of 4 layers deposited at a temperature of 425° C. after spin coating at 4000 RPM for 1 minute. After each spin coating the sample. The sample waited prior to hot plate sintering 20 minutes, 5 minutes, 5 minutes and 20 minutes for settling and further hydrolysis. Here, all samples were crystallized at 300° C. for different periods of time of 1 hour, 5 hours and 24 hours. The graph shows that the higher annealing duration reduces the overall resistivity of the film. At the moment we are limited by the temperature of the hot-plate around 450° C. Also the additional wait time prior to hot-plate sintering is providing additional benefits leading to our current lowest resistivity achieved of 2.32e-2 Ohm·cm.

In FIG. 9, an experiment where graphene oxide nanoparticles were dissolved not in DMF but in N-Methyl-2-pyrrolidone (NMP) and added to a 0.8 atom % Al in ZnO solution based on DMF is shown. The films were produced using a spin coated at 4000 RPM for 30 seconds and a hot plate at 400° C. for 1 minute of annealing. Four layers were deposited in this case. The photograph in this case shows a comparison of the graphene doped AZO films with a bare glass sample.

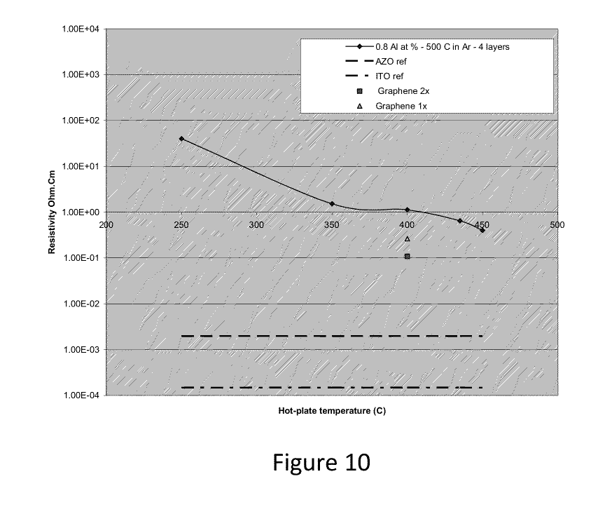

FIG. 10 shows an example of enhancement obtained by co-doping the AZO film with a semiconductor/metallic nanostructured particle. In this case graphene was used to enhance the conductivity of the AZO films. Here solutions of 1× amount of graphene and 2× amount of graphene were used and compared. It is clear that the presence of a metallic/semiconductor nanoparticle with the AZO films led to a reduction resistivity of the film.

It will be apparent to those skilled in the art that various modifications and variations can be made without departing from the spirit or scope of the invention.

What is claimed is:

1. A method comprising:
providing a solution comprising a metallic salt, an organo-metallic compound, or combinations thereof in a polar aprotic solvent;
depositing the solution onto a substrate to form a coating on the substrate; and
annealing the coating.

2. The method according to claim 1, wherein the metallic salt comprises ions of zinc, tin, aluminum, indium, iron, or combinations thereof.

3. The method according to claim 1, wherein the metallic salt comprises ions of tungsten, titanium, zirconium, silicon, silicon nitride, boron, boron nitride, copper, silver, rare earth ions, or combinations thereof.

4. The method according to claim 1, wherein the organo-metallic compound comprises ions of zinc, tin, aluminum, indium, or combinations thereof.

5. The method according to claim 1, wherein the organo-metallic compound comprises ions of tungsten, titanium, zirconium, silicon, silicon nitride, boron, boron nitride, copper, silver, rare earth ions, or combinations thereof.

6. The method according to claim 1, wherein the polar aprotic solvent comprises a pH modifier.

7. The method according to claim 6, wherein the pH modifier is selected from nitric acid, acetic acid, hydrofluoric acid, and combinations thereof.

8. The method according to claim 1, wherein the solvent comprises dimethylformamide, n-methylpyrrolidone, or a combination thereof.

9. The method according to claim 1, further comprising crystallizing the coating after the annealing.

10. The method according to claim 1, wherein the crystallizing comprises crystallizing the annealed coating at a temperature in the range of from 300 to 600° C.

11. The method according to claim 10, wherein the crystallization comprises crystallizing the annealed coating in a controlled environment comprising air, Nitrogen, CO, CO₂, NOX, Xenon, Argon, Oxygen or a combination thereof.

12. The method according to claim 1, comprising alternatingly repeating the depositing and annealing to form multiple coatings on the substrate.

13. The method according to claim 1, further comprising adding semiconductor nanoparticles, metal nanoparticles, or a combination thereof in dimethylformamide, n-methyl pyrrolidone, or a combination thereof to the solution prior to the depositing.

14. The method according to claim 13, comprising nanostructures of graphene, carbon, silver, gold, platinum, metallic, or combinations thereof.

15. The method according to claim 14, wherein the nanostructures are in the form of nanotubes, nanowires, nanodots, nanoparticles or combinations thereof.

16. The method according to claim 1, wherein the depositing comprises spin-coating, dip-coating, spray-coating, tape-casting, ink jet, misting, stamping, or washing the substrate in the solution.

17. The method according to claim 1, wherein the providing comprises mixing zinc acetate dehydrate in dimethylformamide to form a first solution; separately mixing aluminum nitrate in dimethylformamide to form a second solution; and mixing the first and second solution to a desired atom concentration of Al and Zn.

18. The method according to claim 1, wherein the annealing comprises sintering the coating at a temperature in the range of from 300 to 600° C.

19. The method according to claim 1, wherein the depositing is done in a continuous process.

20. The method according to claim 1, wherein the annealing is done in a continuous process.

21. The method according to claim 1, further comprising depositing another film adjacent to the coating.

22. The method according to claim 1, wherein the depositing comprises depositing in a patterning or in descrete regions.

23. The method according to claim 22, wherein the depositing is done by photolithography, masks, silk screening, molds, or combinations thereof.

24. A method comprising:
providing a solution comprising doped zinc or aluminum in a polar aprotic solvent;
depositing the solution onto a substrate to form a coating on the substrate; and
annealing the coating.
